(19) United States
(12) Patent Application Publication
(10) Pub. No.: US 2023/0386967 A1
(43) Pub. Date: Nov. 30, 2023

(54) WAFER PACKAGING SYSTEM AND METHOD FOR MANUFACTURING THE SAME

(71) Applicant: SJ Semiconductor(Jiangyin) Corporation, Jiangyin City (CN)

(72) Inventors: Chengchung Lin, Jiangyin City (CN); Jin Yang, Jiangyin City (CN)

(21) Appl. No.: 18/142,424

(22) Filed: May 2, 2023

(30) Foreign Application Priority Data
May 27, 2022 (CN) 202210591718.7

(51) Int. Cl. H01L 23/473; H01L 25/065; H01L 25/18; H10B 80/00

(52) U.S. Cl. CPC H01L 23/473; H01L 25/0655; H01L 25/18; H10B 80/00

(57) ABSTRACT

A wafer packaging system and a method for manufacturing the same are disclosed; the system comprises: a silicon substrate having a first surface and a second surface opposite to the first surface; a rewiring layer disposed on the first surface of the silicon substrate; a plurality of chips bonded over the rewiring layer; and a structural reinforcement layer, fixed to the second surface of the silicon substrate, wherein liquid cooling channels are formed inside the structural reinforcement layer. The wafer packaging system of the present disclosure integrates a plurality of chips with different functions onto one full-wafer-size platform to improve the packaging performance. A structural reinforcement layer is added to the packaging system, which supports a large silicon substrate platform and enhances the structural rigidity of the whole packaging system. The structural reinforcement layer, along with liquid cooling channels, provides a heat conducting path for heat generated by the system.

### CROSS REFERENCE TO RELATED APPLICATION

The present application claims the benefit of priority to Chinese Patent Application No. CN 2022105917187, entitled “WAFER PACKAGING SYSTEM AND METHOD FOR MANUFACTURING SAME”, filed with CNIPA on May 27, 2022, the disclosure of which is incorporated herein by reference in its entirety for all purposes.

### FIELD OF TECHNOLOGY

The present disclosure generally relates to semiconductor packaging, in particular, to a wafer packaging system and a method for manufacturing the wafer packaging system.

### BACKGROUND

In recent years, flip-chip packaging has emerged as the mainstream electronic packaging solution, accounting for 60% to 70% of the entire integrated circuit packaging market. Driven by growing performance demand in areas like high-performance computing, artificial intelligence, cloud computing, graphics processing units, and autonomous driving, multiple chips with different functions sometimes have to be integrated into a single platform. In the predictable future, autonomous driving will also require a larger amount of data to be processed using a central computing platform which has a high computing power. Currently, standard integrated circuit packaging, such as flip-chip packaging, utilizes an organic substrate as the platform for silicon integration; that is, one or more silicon wafers are attached to an organic substrate. Dimensions of packaging on organic substrates have increased from 50×50 mm 2 to 70×70 mm², and approaching 100×100 mm² now. However, such a substantial increase in dimensions still fails to catch up with the ever-increasing demand for a higher computing power. Thus, more chips need to be integrated into one computing device, which, however, will mean more heat generated during operation. Therefore, how to integrate multiple chips into a suitable platform while improving the heat dissipation capacity of the platform is a challenge facing those skilled in the art.

### SUMMARY

The present disclosure provides a wafer packaging system, comprising: a silicon substrate, wherein the silicon substrate has a first surface and a second surface opposite to the first surface; a rewiring layer disposed on the first surface of the silicon substrate, a plurality of chips, disposed over the rewiring layer and a structural reinforcement layer, fixed to the second surface of the silicon substrate, wherein liquid cooling channels are formed inside the structural reinforcement layer.

The present disclosure further provides a method for manufacturing a wafer packaging system, comprising: providing a silicon substrate with a first surface and a second surface opposite to the first surface; soldering a plurality of chips to the first surface of the silicon substrate; and fixing a structural reinforcement layer to the second surface of the silicon substrate, wherein liquid cooling channels are formed inside the structural reinforcement layer.

The wafer packaging system of the present disclosure integrates a plurality of chips with different functions onto one full-wafer-size platform to improve the packaging performance. A structural reinforcement layer is added to the packaging system, which can support a larger silicon substrate platform therefore enhancing the structural rigidity of the whole packaging system. The structural reinforcement layer, along with liquid cooling channels, also provides a thermal conducting path for heat generated during the operation of the system, thereby enhancing the heat dissipation capability of the system.

### BRIEF DESCRIPTION OF THE DRAWINGS

FIGS. 1 to 3 show schematic cross-sectional views of a wafer packaging system during operations of a method for manufacturing the wafer packaging system.

FIG. 4 shows a schematic top view of the wafer packaging system of FIG. 3.

FIGS. 5 to 6 show top views of a structural reinforcement layer in a wafer packaging system according to embodiments of the present disclosure.

### REFERENCE NUMERALS

1 Silicon substrate
201, 202, 203 Chips
3 Structural reinforcement layer
4 Liquid cooling channels
5 Stack of dielectric layers
6 Stack of patterned wiring metal layers

### DETAILED DESCRIPTION

The present disclosure will be described below through exemplary embodiments. Those skilled in the art can easily understand other advantages and effects of the present disclosure according to contents disclosed by the specification. The present disclosure can also be implemented or applied through other different exemplary embodiments. Various modifications or changes can also be made to all details in the specification based on different points of view and applications without departing from the spirit of the present disclosure.

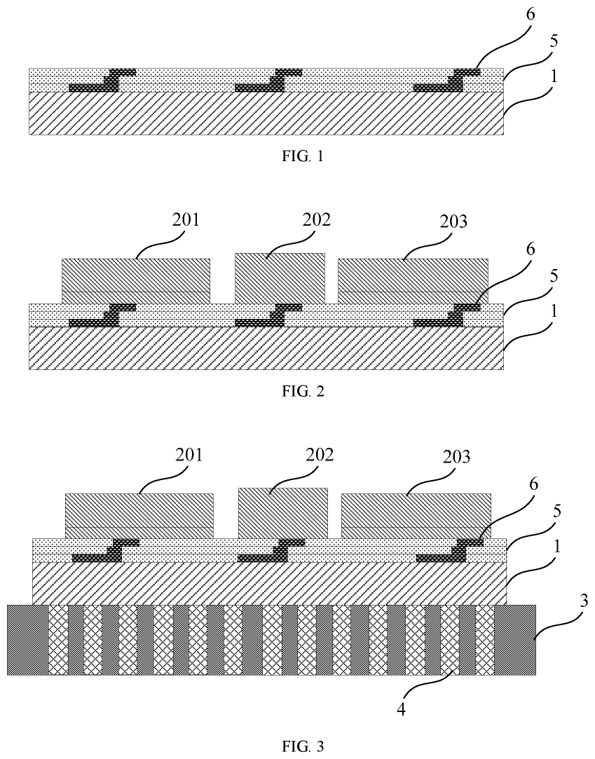

Referring to FIGS. 1-5. It should be noted that the drawings provided in this disclosure only illustrate the basic concept of the present disclosure in a schematic way, so the drawings only show the components closely related to the present disclosure. The drawings are not necessarily drawn according to the number, shape, and size of the components in actual implementation; during the actual implementation, the type, quantity, and proportion of each component can be changed as needed, and the components' layout may also be more complicated.

As shown in FIG. 3, the present disclosure provides a wafer packaging system, comprising: a silicon substrate 1, a plurality of chips 201, 202, 203, and a structural reinforcement layer 3.

The silicon substrate 1 has a first surface and a second surface opposite to the first surface. A rewiring layer is disposed on the first surface of the silicon substrate 1. A plurality of chips 201, 202, 203 is disposed over the rewiring layer. The structural reinforcement layer 3 is fixed to the second surface of the silicon substrate, and liquid cooling channels 4 are formed inside the structural reinforcement layer 3.

As an example, a rewiring layer is formed over the first surface of the silicon substrate 1, the rewiring layer comprises a stack of dielectric layers 5 and a stack of patterned wiring metal layers 6 disposed in the stack of dielectric layers 5, and the chips 201, 202, 203 are electrically connected to the stack of patterned wiring metal layer layers by soldering. That is, electrical connections formed in the stack of patterned wiring metal layers connect the chips 201, 202, 203 at the top to the silicon substrate 1 at the bottom.

The material of the stack of dielectric layers 5 may be one of epoxy resin, silicone, polyimide (PI), piperonyl butoxide (PBO), bisbenzocyclobutene (BCB), silicon oxide, phosphor silica glass, and fluorine-containing glass, and may be formed by processes such as spin coating, chemical vapor deposition (CVD), plasma-enhanced CVD, etc. The stack of patterned wiring metal layers may be a single metal layer or may include two or more metal layers (for simplicity, only one numeral 6 is referred to in the figures), and the material of the stack of patterned wiring metal layers may include one or more of copper, aluminum, nickel, gold, silver, and titanium.

A diameter of the silicon substrate 1 is about 150 mm, 200 mm, or 300 mm (for simplicity, only one exemplary section of the substrate is drawn in the figures).

The chips may be any type of semiconductor chips suitable for packaging, and there may be several chips of the same type and function or several chips with different functions. In one embodiment as shown in the figures, the plurality of chips 201, 202, 203 is chips of different types. For example, each of the chips can be a system-on-chip (SOC) device, a memory chip (such as a high bandwidth memory chip), a logic chip, a power management chip, or an I/O chip, etc. For the sake of illustration, only three chips 201, 202, 203 are shown in the figures.

As an example, the plurality of chips 201, 202, 203 can be soldered to the first surface by hybrid bonding or metal diffusion bonding.

As an example, the structural reinforcement layer 3 has a thickness in the millimeter range, for example, 2 mm, 3 mm, or 5 mm.

As an example, the material of the structural reinforcement layer 3 may be Invar. Invar is an iron-nickel alloy, which has a low coefficient of thermal expansion (in the range of 0.5 to 2.0 ppm/° C.), and therefore, the structural reinforcement layer 3 made of Invar will have a good dimensional stability. The coefficient of thermal expansion of Invar matches well with that of silicon (2.6 ppm/° C.), and the match can sufficiently reduce package deformation caused by temperature changes and improve packaging performance. In addition, Invar has a high Young's modulus of 135 Gpa. Therefore, even if the diameter of the silicon wafer is large, e.g., 200 mm, 300 mm, or larger, the structural reinforcement layer 3 can still provide good structural support and achieve required structural rigidity.

The liquid cooling channels 4 are integrated in the structural reinforcement layer 3. The liquid cooling channels 4 allow the flow of cryogenic liquid to take away the heat generated by the wafer packaging system during operation. Preferably, the liquid cooling channels 4 are copper channels; specifically, the copper channels are hollow and cryogenic liquid flows through the hollow copper channels. The thermal conductivity of copper is as high as 380 W/m/K, and therefore heat can be better carried away and the heat dissipation efficiency can be improved.

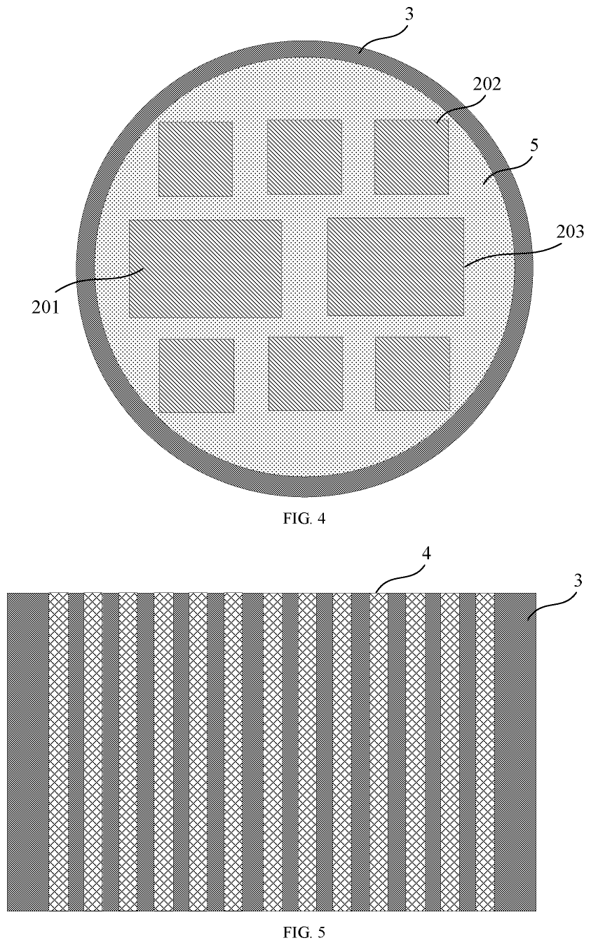

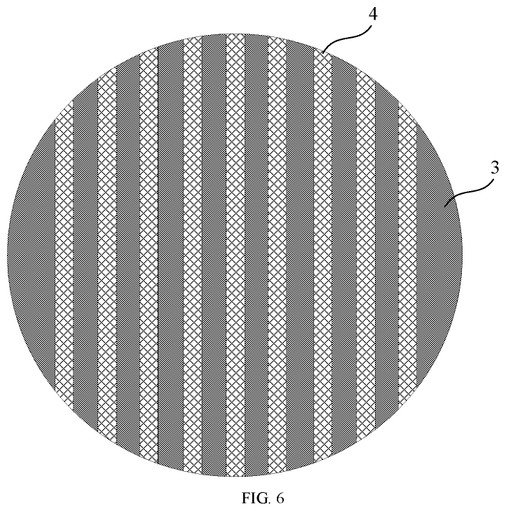

FIG. 4 is a top view of a section of the wafer packaging system of the present disclosure. FIGS. 5 and 6 are top views of sections of the structural reinforcement layer 3. A cross section of the structural reinforcement layer can be circular or square, with the cross-sectional cutting plane parallel to the first surface of the silicon substrate 1; the liquid cooling channels 4 shown are parallel hollow structures.

As an example, the structural reinforcement layer 3 is fixed to the second surface by thermally conductive adhesive or metal bonding.

It should be noted that all the chips are “known good dies”, and are soldered to the silicon substrate 1 after wafer-level testing, to achieve fan-out wafer-level package of chips of different types, thereby forming a wafer-level high-performance integrated package that has the structural reinforcement layer 3 and liquid cooling channels 4 for heat dissipation.

As shown in FIGS. 1 to 3, the present disclosure also provides a method for manufacturing a wafer packaging system, which may be used to prepare the wafer packaging system described above. The method comprises steps detailed below.

Step 1 comprises, as shown in FIG. 1, providing a silicon substrate 1 with a first surface and a second surface opposite to the first surface.

As an example, a rewiring layer is formed over the first surface of the silicon substrate 1, the rewiring layer comprises a stack of dielectric layers 5 and a stack of patterned wiring metal layers disposed in the stack of dielectric layers 5.

The stack of dielectric layers 5 may be made of materials from one of epoxy resin, silicone, polyimide (PI), piperonyl butoxide (PBO), bisbenzocyclobutene (BCB), silicon oxide, phosphor silica glass, and fluorine-containing glass, and may be formed by processes such as spin coating, chemical vapor deposition (CVD), plasma-enhanced CVD, etc. The stack of patterned wiring metal layers may be a single metal layer or may include two or more metal layers, and the material of the stack of patterned wiring metal layers may include one or more of copper, aluminum, nickel, gold, silver, and titanium.

A diameter of the silicon substrate 1 is about 150 mm, 200 mm, or 300 mm.

Step 2 comprises soldering the plurality of chips 201, 202, 203 to the first surface of the silicon substrate, as shown in FIG. 2.

Chips 201, 202, 203 are electrically connected to the stack of patterned wiring metal layers by subsequent soldering. Electrical connections formed in the stack of patterned wiring metal layers connect the chips 201, 202, 203 at the top to the silicon substrate 1 at the bottom. The chips may be any applicable semiconductor chips suitable for packaging, and may be several chips of the same type and function or several chips 201, 202, 203 with different functions. In one embodiment as shown in the figures, the plurality of chips 201, 202, 203 includes different types. For example, each of the chips can be a system-on-chip (SOC) device, a memory chip (such as a high bandwidth memory chip), a logic chip, a power management chip, or an I/O chip, etc. For the sake of illustration, only three exemplary chips 201, 202, 203 are shown in the figures.

As an example, the plurality of chips 201, 202, 203 can be soldered to the first surface by hybrid bonding or metal diffusion bonding.

Step 3 comprises fixing a structural reinforcement layer 3 to the second surface of the silicon substrate, wherein liquid cooling channels 4 are formed inside the structural reinforcement layer 3, as shown in FIG. 3.

As an example, the material of the structural reinforcement layer 3 may be Invar. Invar is an iron-nickel alloy, which has a low coefficient of thermal expansion (0.5 to 2.0 ppm/° C.), and therefore, the structural reinforcement layer 3 made of Invar will have a good dimensional stability. The coefficient of thermal expansion of Invar matches well with that of silicon (2.6 ppm/° C.), and the match can sufficiently reduce package deformation caused by temperature changes and improve packaging performance. In addition, Invar has a high Young's modulus of 135 Gpa. Therefore, even if the diameter of the silicon wafer is large, e.g., 200 mm, 300 mm, or larger, the structural reinforcement layer 3 can still provide good structural support and achieve required structural rigidity.

The liquid cooling channels 4 are integrated in the structural reinforcement layer 3. The liquid cooling channels 4 allow the flow of low-temperature liquid to take away the heat generated by the wafer packaging system during operation. Preferably, the liquid cooling channels 4 are copper channels; specifically, the copper channels are hollow and cryogenic liquid flows through the hollow copper channels. The thermal conductivity of copper is as high as 380 W/m/K, and therefore the heat can be better carried away and the heat dissipation efficiency can be improved.

FIG. 4 is a top view the intermediate structure as shown in FIG. 3, and FIGS. 5 and 6 are top views of the structural reinforcement layer 3. A cross section of the structural reinforcement layer is circular (FIG. 6) or square (FIG. 5), with the cutting plane parallel to the first surface of the silicon substrate 1; the liquid cooling channels 4 are parallel hollow structures.

As an example, the structural reinforcement layer 3 is fixed to the second surface by thermally conductive adhesive or metal bonding.

It should be noted that all the chips are “known good dies”, and are soldered to the silicon substrate 1 after wafer-level testing, to achieve fan-out wafer-level package of chips of different types, thereby forming a wafer-level high-performance integrated package that has the structural reinforcement layer 3 and liquid cooling channels 4 for heat dissipation.

In summary, the present disclosure provides a wafer packaging system and a method for manufacturing the same; the system comprises at least: a silicon substrate having a first surface and a second surface opposite to the first surface; a rewiring layer is disposed on the first surface of the silicon substrate, a plurality of chips is disposed over the rewiring layer; a structural reinforcement layer, fixed to the second surface of the silicon substrate, wherein liquid cooling channels are formed inside the structural reinforcement layer. The wafer packaging system of the present disclosure integrates a plurality of chips with different functions onto one full-wafer-size platform to improve the packaging performance. A structural reinforcement layer is added to the packaging system, which can support a large silicon substrate platform and enhance the structural rigidity of the whole packaging system. The structural reinforcement layer, along with liquid cooling channels, also provides a thermal conducting path for heat generated during the operation of the system, thereby enhancing the heat dissipating capability of the system.

Therefore, the present disclosure effectively overcomes various shortcomings in the existing technology and has high industrial utilization value.

The above embodiments are only illustrative of the principle of the present disclosure and its efficacy, and are not intended to limit the present disclosure. Anyone familiar with this technology can modify or change the above-mentioned embodiments without departing from the spirit and scope of the present disclosure. Therefore, all equivalent modifications or changes made by those who have common knowledge in the art without departing from the spirit and technical concept disclosed by the present disclosure shall be still covered by the claims of the present disclosure.

What is claimed is:

1. A wafer packaging system, comprising:
a silicon substrate, wherein the silicon substrate has a first surface and a second surface opposite to the first surface;
a rewiring layer disposed on the first surface of the silicon substrate;
a plurality of chips bonded over the rewiring layer; and
a structural reinforcement layer, fixed to the second surface of the silicon substrate, wherein liquid cooling channels are formed inside the structural reinforcement layer.

2. The wafer packaging system according to claim 1, wherein the rewiring layer is formed over the first surface of the silicon substrate, wherein the rewiring layer comprises a stack of dielectric layers and a stack of patterned wiring metal layers, wherein the stack of patterned wiring metal layers is disposed in the stack of dielectric layers, and wherein the plurality of chips is electrically connected to the stack of wiring metal layers by soldering.

3. The wafer packaging system according to claim 1, wherein a thickness of the structural reinforcement layer is in the millimeter range.

4. The wafer packaging system according to claim 1, wherein the liquid cooling channels comprises copper channels.

5. The wafer packaging system according to claim 1, wherein a cross section of the structural reinforcement layer parallel to the first surface of the silicon substrate comprises a circle or a square.

6. The wafer packaging system according to claim 1, wherein the structural reinforcement layer is fixed to the second surface by a thermally conductive adhesive or metal bonding.

7. The wafer packaging system according to claim 1, wherein a material of the structural reinforcement layer comprises Inver.

8. The wafer packaging system according to claim 1, wherein a dimension of the silicon substrate is about 150 mm, 200 mm, or 300 mm.

9. A method for manufacturing a wafer packaging system, comprising:
providing a silicon substrate with a first surface and a second surface opposite to the first surface;
forming a rewiring layer on the first surface of the silicon substrate;
bonding a plurality of chips to the rewiring layer; and
fixing a structural reinforcement layer to the second surface of the silicon substrate, wherein liquid cooling channels are formed inside the structural reinforcement layer.

10. The method for manufacturing the wafer packaging system according to claim 9, wherein the rewiring layer comprises a stack of dielectric layers and a stack of patterned wiring metal layers disposed in the stack of dielectric layers, and wherein the plurality of chips is electrically connected to the stack of patterned wiring metal layers by soldering.

11. The method for manufacturing the wafer packaging system according to claim 9, wherein the plurality of the chips is bonded to the rewiring layer by hybrid bonding or metal diffusion bonding.

12. The method for manufacturing the wafer packaging system according to claim 9, wherein the liquid cooling channels comprise copper channels.

13. The method for manufacturing the wafer packaging system according to claim 9, wherein the structural reinforcement layer is fixed to the second surface of the silicon substrate by thermally conductive adhesive or metal bonding.

14. The method for manufacturing the wafer packaging system according to claim 9, wherein a material of the structural reinforcement layer comprises Inver.

15. The method for manufacturing the wafer packaging system according to claim 9, wherein a dimension of the silicon substrate is about 150 mm, 200 mm, or 300 mm.
